(19) United States
(12) Patent Application Publication
(10) Pub. No.: US 2026/0285036 A1
(43) Pub. Date: Sep. 24, 2026

(54) INKJET PRINTING APPARATUS, METHOD OF MANUFACTURING DISPLAY MODULE USING THE SAME AND ELECTRONIC DEVICE

(71) Applicant: Samsung Display Co., Ltd., Yongin-si (KR)

(72) Inventor: Mamoru WAKABAYASHI, Yokohama-shi (JP)

(21) Appl. No.: 19/563,441

(22) Filed: Mar. 11, 2026

(30) Foreign Application Priority Data
Mar. 19, 2025 (JP) 2025-044364

(51) Int. Cl. B41J 2/045; B41J 2/205; B41J 11/00; H10K 71/13

(52) U.S. Cl. CPC B41J 2/04573; B41J 2/04505; B41J 2/04508; B41J 2/205; B41J 11/008; H10K 71/135; B41J 2/04581

(57) ABSTRACT

An inkjet printing apparatus includes a stage, a support table above the stage and to which a target substrate is fixed, a first mover configured to move the support table in a first-axis direction above the stage, a head unit above the target substrate, configured to eject ink onto a printing area of the target substrate, and configured to set an ejection timing of the ink differently depending on an ejection amount of the ink, and a second mover configured to move the head unit in a second-axis direction.

### CROSS-REFERENCE TO RELATED APPLICATION

The present application claims priority to, and the benefit of, Japan Patent Application No. 2025-044364, filed on Mar. 19, 2025, in the Japanese Intellectual Property Office, the entire disclosure of which is incorporated herein by reference.

### BACKGROUND

Embodiments of the present disclosure described herein relate to an inkjet printing apparatus, a method of manufacturing a display module using the same, and an electronic device.

Multimedia devices, such as a television, a mobile phone, a tablet computer, a navigation system, a game console, and the like, may be equipped with a display panel for displaying an image. The display panel may include a plurality of pixels for displaying an image, each of which may include a light-emitting element that generates light, and a driving element connected to the light-emitting element.

Inkjet printing apparatuses are used in the manufacture of display panels. The inkjet printing apparatuses may form a desired layer on a display panel by printing an organic material (or ink) onto a substrate.

High-resolution and precise patterning processes are required in the manufacture of display panels. As a pixel size of the display panel decreases due to higher resolution, the inkjet printing apparatus should eject a smaller amount of ink. When the amount of ink ejected by the inkjet printing apparatus is not precisely controlled, defects may occur.

### SUMMARY

Embodiments of the present disclosure provide an inkjet printing apparatus with a reduced defect rate, a method for manufacturing a display module using the same, and an electronic device.

According to one or more embodiments of the present disclosure, an inkjet printing apparatus includes a stage, a support table above the stage and to which a target substrate is fixed, a first mover configured to move the support table in a first-axis direction above the stage, a head unit above the target substrate, configured to eject ink onto a printing area of the target substrate, and configured to set an ejection timing of the ink differently depending on an ejection amount of the ink, and a second mover configured to move the head unit in a second-axis direction.

The head unit may include an inkjet head, and nozzles on a lower surface of the inkjet head and including a first nozzle configured to eject the ink in a first ejection amount, a second nozzle configured to eject the ink in a second ejection amount that is less than the first ejection amount, and a third nozzle configured to eject the ink in a third ejection amount that is less than the second ejection amount.

The head unit may be configured to receive a position signal indicating a position of the target substrate, and is configured to determine the ejection timing of the ink with respect to the first nozzle, the second nozzle, and the third nozzle based on the position signal and the first ejection amount, the second ejection amount, and the third ejection amount.

The third nozzle may be configured to eject the ink at a first ejection time point that is delayed by a first delay time from an initiation time point of the position signal, wherein the second nozzle is configured to eject the ink at a second ejection time point that is delayed by a second delay time from the initiation time point that is greater than the first delay time, and wherein the first nozzle is configured to eject the ink at a third ejection time point that is delayed by a third delay time from the initiation time point that is greater than the second delay time.

The head unit may further include an image analyzer configured to receive and analyze print image data to extract a command with respect to the ejection timing of the ink of the nozzles, an ejection control signal generator configured to generate an ejection control signal based on the position signal, and an ejection control signal corrector configured to receive the command from the image analyzer, to receive the ejection control signal from the ejection control signal generator, and to change an activation timing of the ejection control signal based on the command to generate a compensation ejection control signal.

The head unit may further include a mask configured to receive the print image data from the image analyzer and to output compensation print image data by masking the command among the print image data.

A print image corresponding to the print image data may include an ejection data area including grayscale areas including ejection amount information with respect to a corresponding nozzle, and a command area including grayscale areas including information with respect to the ejection timing of the ink of the corresponding nozzle.

A first one of the grayscale areas corresponding to the first nozzle may have a first reference grayscale, wherein a second one of the grayscale areas corresponding to the second nozzle has a second reference grayscale, wherein a third one of the grayscale areas corresponding to the third nozzle has a third reference grayscale, and wherein the first reference grayscale, the second reference grayscale, and the third reference grayscale have different respective values.

One or more of the grayscale areas of the ejection data area may have a white grayscale, wherein the head unit is configured to turn off the nozzle corresponding to the one or more of the grayscale areas having the white grayscale.

The grayscale areas of the command area may have one of a first command grayscale or a second command grayscale, wherein the first command grayscale and the second command grayscale are two different grayscales from among the first reference grayscale, the second reference grayscale, the third reference grayscale, and the white grayscale.

A compensation print image corresponding to the compensation print image data may include the ejection data area and a masking area that corresponds to the command area of the print image.

The masking area may include one or more of the grayscale areas having the white grayscale such that one or more of the nozzles corresponding to the masking area are configured to be turned off.

According to one or more embodiments of the present disclosure, a method of manufacturing a display module includes fixing a target substrate to a support table above a stage, moving the support table in a first-axis direction above the stage by a first mover, placing a head unit, which is configured to eject ink onto a printing area of the target substrate, above the target substrate, moving the head unit in a second-axis direction above the target substrate by a second mover, determining an ejection amount of the ink and an ejection timing of the ink based on print image data and a position signal, and ejecting the ink onto the printing area to form a pattern layer.

The head unit may include an inkjet head, and nozzles on a lower surface of the inkjet head and including a first nozzle configured to eject the ink in a first ejection amount, a second nozzle configured to eject the ink in a second ejection amount that is less than the first ejection amount, and a third nozzle configured to eject the ink in a third ejection amount that is less than the second ejection amount.

The method may further include receiving, by the head unit, the position signal indicating a position of the target substrate, and determining the ejection timing of the ink of the first nozzle, the second nozzle, and the third nozzle based on the position signal and the first ejection amount, the second ejection amount, and the third ejection amount.

The third nozzle may be configured to eject the ink at a first ejection time point that is delayed by a first delay time from an initiation time point of the position signal, wherein the second nozzle is configured to eject the ink at a second ejection time point that is delayed by a second delay time from the initiation time point that is greater than the first delay time, and wherein the first nozzle is configured to eject the ink at a third ejection time point that is delayed by a third delay time from the initiation time point that is greater than the second delay time.

The determining of the ejection amount of the ink and the ejection timing of the ink may include analyzing the print image data to extract a command with respect to the ejection timing the ink of the nozzles, generating an ejection control signal based on the position signal, and generating a compensation ejection control signal by changing an activation timing of the ejection control signal based on the command.

The determining of the ejection amount of the ink and the ejection timing of the ink may further include outputting compensation print image data by masking the command among the print image data, wherein the method further includes controlling, with the inkjet head, the ejection amount and the ejection timing of the ink with respect to the nozzles in response to the compensation print image data and the compensation ejection control signal.

A print image corresponding to the print image data may include an ejection data area including grayscale areas including ejection amount information with respect to a corresponding nozzle, and a command area including grayscale areas including information with respect to the ejection timing of the ink of the corresponding nozzle, wherein a compensation print image corresponding to the compensation print image data includes the ejection data area and a masking area that corresponds to the command area of the print image, and wherein the method further includes turning off all of ones of the nozzles corresponding to the masking area.

According to one or more embodiments of the present disclosure, an electronic device includes a display module configured to display an image, and a processor configured to process and provide an image signal to the display module, wherein the display module is manufactured by fixing a target substrate to a support table above a stage, moving the support table in a first-axis direction above the stage by a first mover, placing a head unit that is configured to eject ink onto a printing area of the target substrate above the target substrate, moving the head unit in a second-axis direction above the target substrate by a second mover, determining an ejection amount of the ink and an ejection timing of the ink based on print image data and a position signal, and ejecting the ink onto the printing area to form a pattern layer.

The display module is manufactured by operations of fixing a target substrate on a support table fixed or coupled to a stage, moving the support table in a first-axis direction on the stage by a first mover, placing a head unit, which ejects ink onto a printing area of the target substrate, on or above the target substrate, moving the head unit in a second-axis direction on the target substrate by a second mover, determining an ejection amount of the ink and an ejection timing of the ink based on print image data and a position signal, and ejecting the ink onto the printing area to form a pattern layer.

### BRIEF DESCRIPTION OF THE DRAWINGS

The above and other aspects of the present disclosure will become apparent by describing in detail embodiments thereof with reference to the accompanying drawings.

FIG. 1 is a perspective view of an electronic device, according to one or more embodiments of the present disclosure.

FIG. 2 is an exploded perspective view of an electronic device, according to one or more embodiments of the present disclosure.

FIG. 3 is a cross-sectional view of a display module, according to one or more embodiments of the present disclosure.

FIG. 4A is a cross-sectional view of a display module, according to one or more embodiments of the present disclosure.

FIG. 4B is an enlarged cross-sectional view of a portion of a display module, according to one or more embodiments of the present disclosure.

FIG. 5 is a cross-sectional view illustrating one step of a method for manufacturing a display module, according to one or more embodiments of the present disclosure.

FIG. 6 is a plan view illustrating an inkjet printing apparatus, according to one or more embodiments of the present disclosure.

FIG. 7 is a diagram illustrating an ink drop speed depending on an ink ejection amount of a nozzle, according to one or more embodiments of the present disclosure.

FIG. 8A is a diagram illustrating an ink ejection timing and a printing position depending on an ink ejection amount according to a comparative example.

FIG. 8B is a diagram illustrating an ink ejection timing and a printing position depending on an ink ejection amount according to one or more embodiments of the present disclosure.

FIG. 9 is a block diagram of an inkjet printing apparatus, according to one or more embodiments of the present disclosure.

FIG. 10A is a plan view illustrating print image data illustrated in FIG. 9 as an image.

FIG. 10B is a plan view illustrating compensation print image data illustrated in FIG. 9 as an image.

FIG. 11A is a plan view illustrating print image data illustrated in FIG. 9 as an image.

FIG. 11B is a plan view illustrating compensation print image data illustrated in FIG. 9 as an image.

FIG. 12 is a block diagram of an electronic device according to one or more embodiments.

FIG. 13 is a schematic diagram illustrating electronic devices, according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, if a first part is described as being arranged “on” a second part, this indicates that the first part is arranged at an upper side or a lower side of the second part without the limitation to the upper side thereof on the basis of the gravity direction.

Further, the phrase “in a plan view” means if an object portion is viewed from above, and the phrase “in a schematic cross-sectional view” means if a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that if an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, if a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, if a portion of a layer, a film, an area, a plate, or the like is formed on another portion, a forming direction is not limited to an upper direction but includes forming the portion on a side surface or in a lower direction. On the contrary, if a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that if an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. The terms or words used in the present specification and claims are not to be limitedly interpreted as general or dictionary meanings and should be interpreted as meanings and concepts that are consistent with aspects of the present disclosure on the basis that an inventor can be their own lexicographer to appropriately define concepts of terms to describe the embodiments in the best way.

As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments of the present disclosure will be described with reference to accompanying drawings.

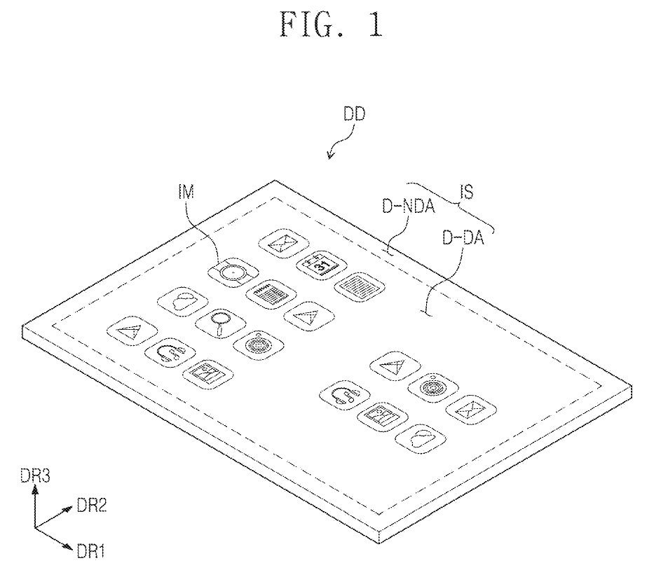

FIG. 1 is a perspective view illustrating an electronic device DD, according to one or more embodiments of the present disclosure.

The electronic device DD may be a display device that is activated by an electrical signal and displays an image IM. The electronic device DD may include various embodiments that provide the image IM to a user. For example, the electronic device DD may be employed in large devices, such as televisions, outdoor billboards, etc., as well as small- and medium-sized devices, such as monitors, mobile phones, tablets, navigation systems, game consoles, etc. The embodiments of the electronic device DD described above are examples and are not limited to any one of them unless they deviate from the concept of the present disclosure.

Referring to FIG. 1, the electronic device DD may have a rectangular shape having long sides extending in a first direction DR1 on a plane and short sides extending in a second direction DR2 on the plane. However, the electronic device DD is not limited thereto, and may have various shapes, such as a circular shape or a polygonal shape that is not a rectangular shape on the plane.

The electronic device DD may display the image IM in a third direction DR3 through a display surface IS parallel to a plane defined by the first direction DR1 and the second direction DR2. The third direction DR3 may be substantially parallel to a normal direction of the display surface IS. The display surface IS on which the image IM is displayed may correspond to a front surface of the electronic device DD. The image IM may include a still image as well as a moving image. FIG. 1 illustrates icon images as an example of the image IM.

FIG. 1 illustrates the electronic device DD having the display surface IS of a flat type as an example. However, without being limited thereto, the display surface IS of the electronic device DD may further include a curved surface bent from a flat surface.

The front surface (or upper surface) and a rear surface (or lower surface) of the members forming the electronic device DD may be defined based on the third direction DR3. The front surface and the rear surface may be opposed to each other in the third direction DR3, and the normal direction of each of the front surface and the rear surface may be parallel to the third direction DR3. The distance between the front surface and the rear surface defined along the third direction DR3 may correspond to the thickness of the member.

In this specification, “on a plane” may be defined as a state viewed from the third direction DR3. In this specification, “in cross section” may be defined as a state viewed from the first direction DR1 or the second direction DR2. However, the directions indicated by the first to third directions DR1, DR2, and DR3 are relative concepts and may be converted into other directions.

The electronic device DD may have a flexible structure. The “flexible” means a characteristic that may be bent, and may include everything from a completely foldable structure to a structure that may be bent to a level of several nanometers. For example, the flexible electronic device DD may include a curved device, a rollable device, a slidable device, or a foldable device. However, the electronic device DD may have a rigid structure, without being limited thereto.

The display surface IS of the electronic device DD may include a display portion D-DA and a non-display portion D-NDA. The display portion D-DA may be a portion within the front surface of the electronic device DD in which the image IM is displayed, and a user may view the image IM through the display portion D-DA. Although FIG. 1 illustrates the display portion D-DA having a rectangular shape on a plane as an example, the shape of the display portion D-DA may be variously changed depending on the design of the electronic device DD.

The non-display portion D-NDA may be a portion within the front surface of the electronic device DD in which the image IM is not displayed. The non-display portion D-NDA may be a portion having a color (e.g., predetermined color) and blocking light. The non-display portion D-NDA may be adjacent to the display portion D-DA. For example, the non-display portion D-NDA may be located on the outside of the display portion D-DA, and may surround the display portion D-DA (e.g., in plan view). However, this is merely an example, and the non-display portion D-NDA may be adjacent to only one side of the display portion D-DA or located in a side surface other than the front surface of the electronic device DD, but embodiments of the present disclosure is not limited thereto, and the non-display portion D-NDA may be omitted.

The electronic device DD may sense an external input applied from the outside. The external input may take various forms, such as pressure, temperature, light, etc. provided from the outside. The external input may include an input (e.g., contact by the user’s hand or a pen) that contacts the electronic device DD, as well as an input (e.g., hovering) that is applied in proximity to the electronic device DD.

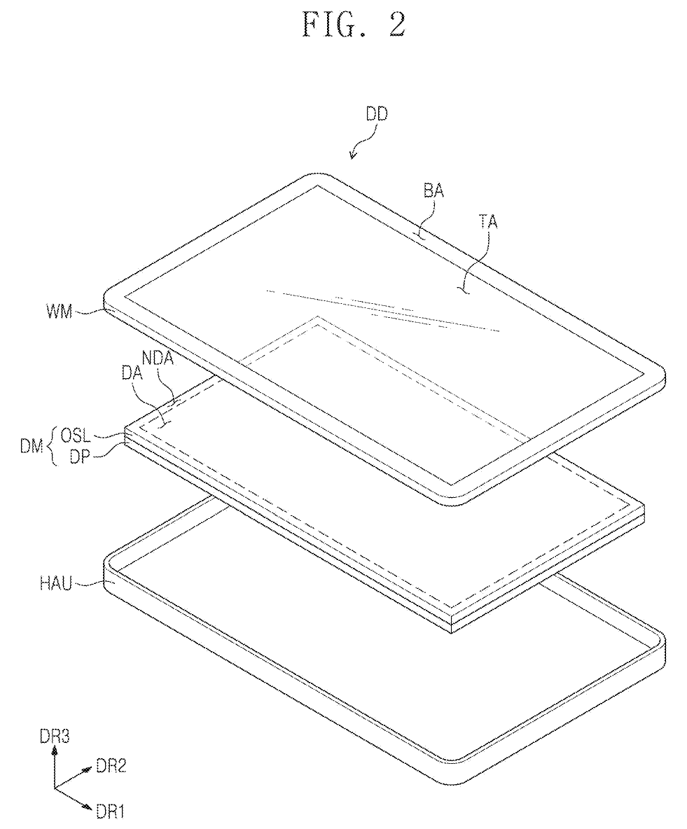

FIG. 2 is an exploded perspective view of the electronic device DD, according to one or more embodiments of the present disclosure.

Referring to FIG. 2, the electronic device DD may include a window WM, a display module DM, and a housing HAU.

The window WM and the housing HAU may be combined to form an exterior of the electronic device DD and may provide an internal space capable of accommodating components of the electronic device DD, such as the display module DM.

The window WM may be located on the display module DM (as used herein, “located on” may mean “above”). The window WM may protect the display module DM from external impact. A front surface of the window WM may correspond to the display surface IS (refer to FIG. 1) of the electronic device DD described above. The front surface of the window WM may include a transmissive area TA and a bezel area BA.

The transmissive area TA of the window WM may be an optically transmissive area. The window WM may transmit the image provided by the display module DM through the transmissive area TA, and the user may view the image. The transmissive area TA may correspond to the display portion D-DA (refer to FIG. 1) of the electronic device DD described above.

The window WM may include an optically transparent insulating material. For example, the window WM may include glass, sapphire, or plastic. The window WM may have a single-layer or a multi-layer structure. The window WM may further include a functional layer, such as an anti-fingerprint layer, a phase control layer, and/or a hard coating layer, located on an optically transparent substrate.

The bezel area BA of the window WM may be provided as an area on which a material having a color (e.g., predetermined color) is deposited, coated, or printed on a transparent substrate. The bezel area BA of the window WM may reduce or prevent visibility (from the outside) of one component of the display module DM overlapping the bezel area BA. The bezel area BA may correspond to the non-display portion D-NDA (refer to FIG. 1) of the electronic device DD described above.

The display module DM may be located between the window WM and the housing HAU. The display module DM may display an image according to an electrical signal. The display module DM may include a display area DA and a non-display area NDA adjacent to the display area DA.

The display area DA may be an area that is activated by an electrical signal and outputs the image. The display area DA of the display module DM may overlap the transmissive area TA of the window WM. Meanwhile, in the present specification, “areas/portions and areas/portions overlap each other” is not limited to having the same area and/or the same shape. The image output from the display area DA may be visually recognized from the outside through the transmissive area TA.

The non-display area NDA may be adjacent to the display area DA. For example, the non-display area NDA may surround the display area DA. However, embodiments of the present disclosure are not limited thereto, and the non-display area NDA may be defined in various shapes. The non-display area NDA may be an area where driving circuits for driving elements that are placed in the display area DA, signal lines for providing electrical signals to the elements, and pads are placed. The non-display area NDA of the display module DM may overlap the bezel area BA of the window WM, and visual recognition of components arranged in the non-display area NDA (from the outside) may be reduced or prevented by the bezel area BA.

The housing HAU may be located under the display module DM to accommodate the display module DM. The housing HAU may absorb impact applied to the display module DM from the outside and protect the display module DM by reducing or preventing foreign substances/moisture, etc. from penetrating into the display module DM. In one or more embodiments, the housing HAU may be provided in a form in which a plurality of accommodation members are combined.

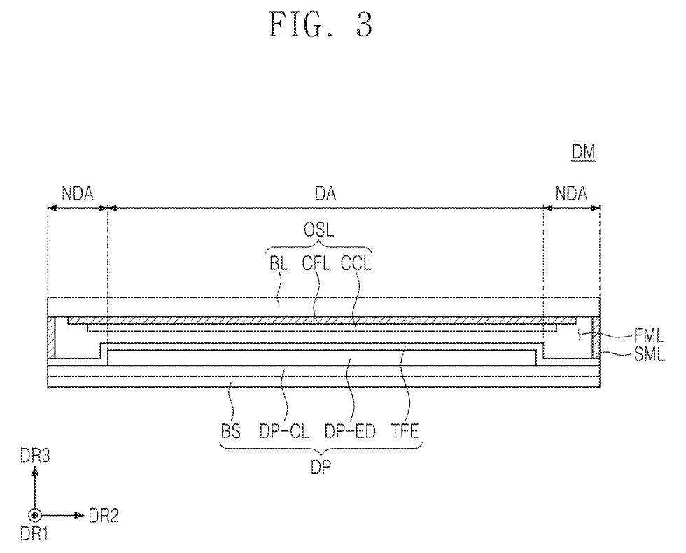

FIG. 3 is a cross-sectional view of the display module DM, according to one or more embodiments of the present disclosure.

Referring to FIGS. 2 and 3, the display module DM may include a display panel DP and an optical control layer OSL located on the display panel DP.

The display panel DP according to one or more embodiments may be a light-emitting display panel, but embodiments of the present disclosure are not particularly limited thereto. For example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, etc. Hereinafter, it is described that the display panel DP is an organic light-emitting display panel.

The display panel DP may include a base substrate BS, a circuit layer DP-CL, a display element layer DP-ED, and an encapsulation layer TFE.

The base substrate BS may provide a base surface on which the circuit layer DP-CL is arranged. The base substrate BS may be a rigid substrate or a flexible substrate. The base substrate BS may include a glass or a synthetic resin layer. The synthetic resin layer may include a thermosetting resin material. For example, the synthetic resin layer may be a polyimide-based resin layer, and the material thereof is not specifically limited. In addition, the base substrate BS may include a glass substrate, a metal substrate, or an organic/inorganic composite material substrate.

The circuit layer DP-CL may be arranged on the base substrate BS. The circuit layer DP-CL may include driving elements, such as transistors, signal lines, and pads. The circuit layer DP-CL may include an insulating layer, a semiconductor pattern, a conductive pattern, and a signal line. The insulating layer, the semiconductor layer, and the conductive layer may be formed on the base substrate BS by a coating, deposition, or the like, and the insulating layer, the semiconductor layer, and the conductive layer may be selectively patterned through multiple photolithography processes. Accordingly, a semiconductor pattern, a conductive pattern, and a signal line may be formed on the base substrate BS. The circuit layer DP-CL may include a transistor, a buffer layer, and a plurality of insulating layers.

The display element layer DP-ED may include light-emitting elements arranged to overlap the display area DA. The light-emitting elements of the display element layer DP-ED may be electrically connected to the driving elements of the circuit layer DP-CL and may output light through the display area DA according to a signal of the driving element.

The encapsulation layer TFE may be located on the display element layer DP-ED to seal the light-emitting elements. The encapsulation layer TFE may include thin films for improving the optical efficiency of the light-emitting elements or protecting the light-emitting elements.

The optical control layer OSL may be located on the display panel DP. The optical control layer OSL may be manufactured through a manufacturing process separate from the manufacturing process of the display panel DP and may be combined on the display panel DP. For example, the optical control layer OSL may be provided on the display panel DP and then combined with the display panel DP through a bonding process using a sealing member SML.

However, embodiments of the present disclosure are not limited thereto, and the optical control layer OSL may be directly located on the display panel DP. In the present specification, the term “directly located” may be used to refer to a state in which a separate adhesive layer or a separate adhesive member is not located and is formed through a continuous process. For example, the term “the optical control layer OSL is directly located on the display panel DP” may refer to a state in which the optical control layer OSL is formed through the continuous process on a base surface provided by the display panel DP after the display panel DP is formed.

The optical control layer OSL may convert the wavelength of light provided by the display panel DP, for example, source light, or may selectively transmit the source light. In addition, the optical control layer OSL may control the optical properties of external light incident from the outside of the electronic device DD to reduce an external light reflectance.

The optical control layer OSL may include a base layer BL, a color filter layer CFL, and a light conversion layer CCL. The base layer BL may be located facing the base substrate BS of the display panel DP, and the color filter layer CFL and the light conversion layer CCL located on the base layer BL may be positioned between the display panel DP and the base layer BL.

The light conversion layer CCL may convert the optical properties of the source light provided by the display panel DP. For example, the light conversion layer CCL may include a quantum dot that converts the wavelength of the source light provided by the display panel DP. The source light passing through the quantum dot included in the light conversion layer CCL may be output as a light having a color different from the color of the source light. The light conversion layer CCL may further include a transmission portion that transmits the source light provided by the display panel DP.

The color filter layer CFL may include color filters each having a color (e.g., predetermined color). The color filters may transmit or absorb the light passing through the light conversion layer CCL depending on the colors of the color filters. The color filter layer CFL may absorb light that is not converted by the light conversion layer CCL to reduce or prevent degradation of the color purity or color reproducibility of the electronic device DD.

The color filters of the color filter layer CFL may absorb external light incident from the outside of the electronic device DD depending on the colors of the color filters. The color filters may filter external light into the same color as the color of the light output through the pixels, thereby reducing the external light reflectance.

The sealing member SML is located in the non-display area NDA, which is an outer part of the display module DM, to reduce or prevent foreign substances, oxygen, or moisture from flowing into the display module DM from the outside. The sealing member SML may be formed from a sealant containing a curable resin.

The display module DM may further include a filling layer FML located between the display panel DP and the optical control layer OSL. The filling layer FML may fill a space between the display panel DP and the optical control layer OSL. The filling layer FML may function as a buffer between the display panel DP and the optical control layer OSL. The filling layer FML may absorb impact and increase the strength of the display module DM.

The filling layer FML may include a polymer resin. For example, the filling layer FML may include an acrylic resin or an epoxy resin. However, in one or more embodiments, because the optical control layer OSL is directly located on the display panel DP, the filling layer FML and the sealing member SML may be omitted. In addition, in one or more embodiments where the optical control layer OSL is directly located on the display panel DP, because the display panel DP provides the base surface, the base layer BL of the optical control layer OSL may be omitted.

Meanwhile, the electronic device DD may further include an input detection module. The input detection module may obtain coordinate information of an external input applied from outside of the electronic device DD. The input detection module may be driven in various ways, such as a capacitive method, a resistive method, an infrared method, or a pressure method, and is not particularly limited.

In one or more embodiments, the input detection module may be placed on the display module DM. The input detection module may be directly located on the display module DM through a continuous process, or may be attached to the display module DM through a separate adhesive layer, without being limited thereto. In addition, the input detection module may be located between the components of the display module DM. For example, the input detection module may be located between the display panel DP and the optical control layer OSL.

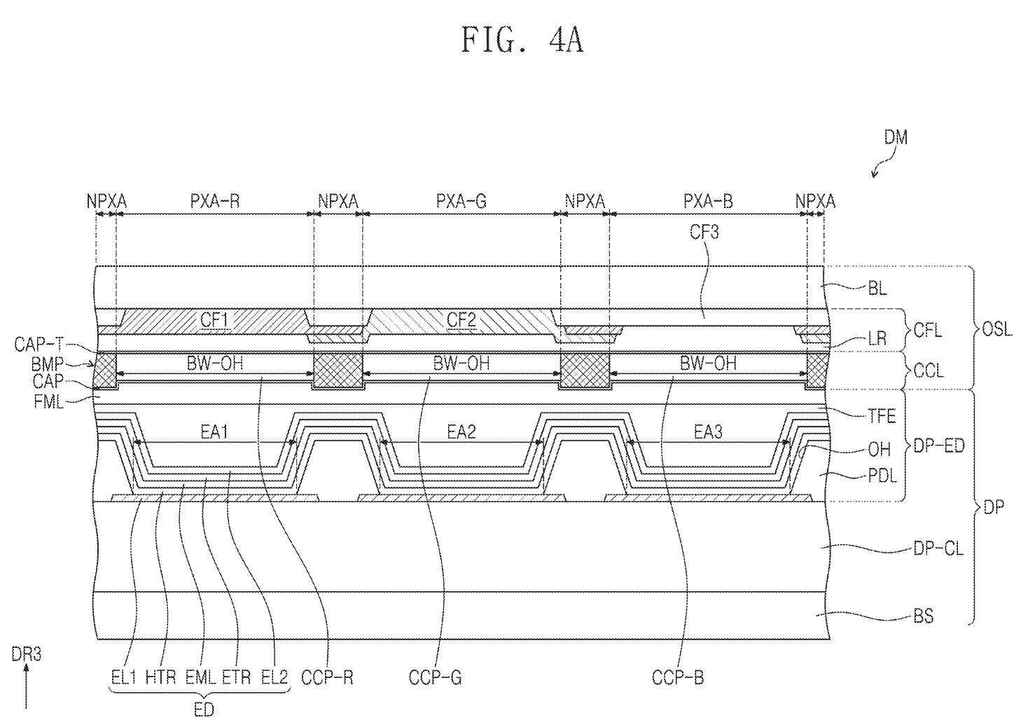

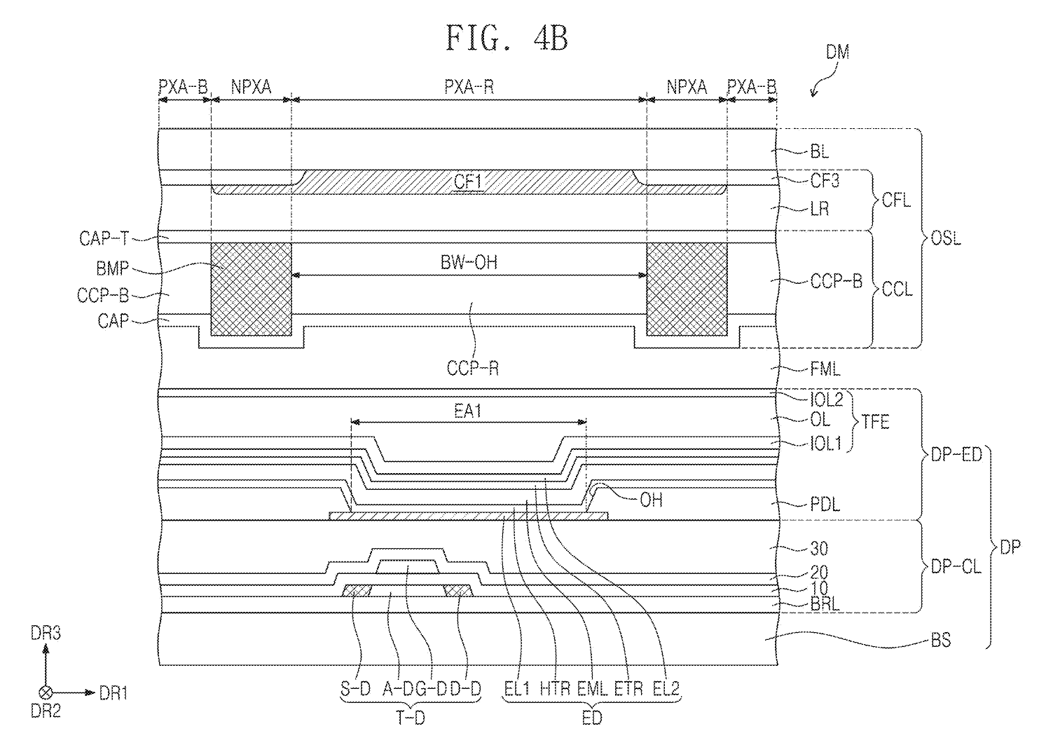

FIG. 4A is a cross-sectional view of a display module, according to one or more embodiments of the present disclosure, and FIG. 4B is an enlarged cross-sectional view of a portion of a display module, according to one or more embodiments of the present disclosure.

Referring to FIGS. 4A and 4B, the display module DM of one or more embodiments may include the base substrate BS, the circuit layer DP-CL located on the base substrate BS, and the display element layer DP-ED located on the circuit layer DP-CL.

The circuit layer DP-CL may be arranged on the base substrate BS. The circuit layer DP-CL may include a transistor T-D as a circuit element. FIG. 4B illustrates the single transistor T-D and the arrangement of an active region A-D, a source region S-D, a drain region D-D, and a gate region G-D constituting the transistor T-D as an example. The active region A-D, the source region S-D, and the drain region D-D may be regions differentiated according to the doping concentration or conductivity of the semiconductor pattern.

The circuit layer DP-CL may include a lower buffer layer BRL, a first insulating layer 10, a second insulating layer 20, and a third insulating layer 30 located on the base substrate BS. For example, the lower buffer layer BRL, the first insulating layer 10, and the second insulating layer 20 may be inorganic layers, and the third insulating layer 30 may be an organic layer.

The display element layer DP-ED may include a light-emitting element ED as a display element. The light-emitting element ED may generate the source light described above. The light-emitting element ED includes a first electrode EL1, a second electrode EL2, and an emission layer EML located the first electrode EL1 and the second electrode EL2. The display element layer DP-ED may include an organic light-emitting diode as the light-emitting element. In one or more embodiments of the present disclosure, the light-emitting element ED may include a quantum dot light-emitting diode. That is, the emission layer EML included in the light-emitting element ED may include an organic light-emitting material as the light-emitting material, or the emission layer EML may include quantum dots as the light-emitting material. Alternatively, the display element layer DP-ED may include an ultra-small light-emitting element as the light-emitting element. The ultra-small light-emitting element may include, for example, a micro-LED element and/or a nano-LED element. The ultra-small light-emitting element may be a light-emitting element having a micro-scale size or a nano-scale size and including an active layer located between a plurality of semiconductor layers.

The first electrode EL1 is located on the third insulating layer 30. The first electrode EL1 may be referred to as an anode or a cathode. The first electrode EL1 may be directly or indirectly connected to the transistor T-D. The connection structure between the first electrode EL1 and the transistor T-D is not illustrated in FIG. 4B.

The display element layer DP-ED includes a pixel-defining film PDL. For example, the pixel-defining film PDL may be an organic layer. Light-emitting apertures OH are defined in the pixel-defining film PDL. Each of the light-emitting apertures OH of the pixel-defining film PDL exposes at least a portion of the first electrode EL1. First to third light-emitting areas EA1, EA2, and EA3 may be defined by the light-emitting apertures OH. The first light-emitting area EA1, the second light-emitting area EA2, and the third light-emitting area EA3 may correspond to a first pixel area PXA-R, a second pixel area PXA-G, and a third pixel area PXA-B, respectively. A non-pixel area NPXA may be defined between the first to third pixel areas PXA-R, PXA-G, and PXA-B.

The first electrode EL1 may be arranged to correspond to the first to third pixel areas PXA-R, PXA-G, and PXA-B and may not be arranged in the non-pixel area NPXA.

A hole control layer HTR may be arranged between the first electrode EL1 and the emission layer EML. The hole control layer HTR may include at least one of a hole injection layer, a hole transport layer, or an electron-blocking layer. The hole control layer HTR may be arranged as a common layer to overlap the first to third light-emitting areas EA1, EA2, and EA3 and the non-pixel area NPXA. However, the present disclosure is not limited thereto, and the hole control layer HTR may be patterned so as to be arranged separately corresponding to each of the first to third light-emitting areas EA1, EA2, and EA3.

The emission layer EML is located on the hole control layer HTR. The emission layer EML may have a single layer made of a single material, a single layer made of multiple different materials, or a multilayer structure including multiple layers made of multiple different materials. The emission layer EML may include a fluorescent material or a phosphorescent material. In one or more embodiments, the light-emitting element may include an organic light-emitting material, a metal-organic complex, or a quantum dot as a light-emitting material. Meanwhile, while FIGS. 4A and 4B illustrate the light-emitting element ED including the single emission layer EML, in one or more embodiments, the light-emitting element ED may include multiple light-emitting stacks, each of which includes at least one emission layer.

In one or more embodiments, the emission layer EML may be provided as a common layer to overlap the first to third light-emitting areas EA1, EA2, and EA3 and the non-pixel area NPXA. In one or more embodiments, the emission layer EML may emit blue light. The emission layer EML may overlap the hole control layer HTR. However, the present disclosure is not limited thereto, and in one or more embodiments, the emission layer EML may be located within the light-emitting apertures OH. In detail, the emission layer EML may be formed separately to correspond to each of the first to third light-emitting areas EA1, EA2, and EA3 defined by the pixel-defining film PDL. The emission layers EML, which are formed separately to correspond to the first to third light-emitting areas EA1, EA2, and EA3, may all emit blue light or may emit light of different wavelength ranges.

An electron control layer ETR is located between the emission layer EML and the second electrode EL2. The electron control layer ETR may include at least one of an electron transport layer, an electron injection layer, or a hole-blocking layer. The electron control layer ETR may be arranged as a common layer to overlap the first to third light-emitting areas EA1, EA2, and EA3 and the non-pixel area NPXA. However, the present disclosure is not limited thereto, and the electron control layer ETR may be patterned so as to be arranged separately corresponding to each of the first to third light-emitting areas EA1, EA2, and EA3.

The second electrode EL2 is located on the electron control layer ETR. The second electrode EL2 may be referred to as an anode or a cathode. When the first electrode EL1 is the anode, the second electrode EL2 may be the cathode, and when the first electrode EL1 is the cathode, the second electrode EL2 may be the anode. The second electrode EL2 may be arranged as a common layer to overlap the first to third light-emitting areas EA1, EA2, and EA3 and the non-pixel area NPXA.

The display element layer DP-ED may include the encapsulation layer TFE that protects the second electrode EL2. The encapsulation layer TFE may include an organic material or an inorganic material. The encapsulation layer TFE may have a multilayer structure with alternating inorganic and organic layers. The encapsulation layer TFE may include a first inorganic layer IOL1, an organic layer OL, and a second inorganic layer IOL2. The first and second inorganic layers IOL1 and IOL2 protect the light-emitting element ED from external moisture, and the organic layer OL reduces or prevents denting defects in the light-emitting element ED caused by foreign substances introduced during the manufacturing process. In one or more embodiments, the display panel DP may further include a refractive index control layer on top of the encapsulation layer TFE to improve light output efficiency.

The optical control layer OSL is located on the encapsulation layer TFE. The optical control layer OSL may include the light conversion layer CCL, the color filter layer CFL, and the base layer BL. In this specification, the optical control layer OSL may be referred to as an upper panel or an optical substrate.

The light conversion layer CCL may be located on the display element layer DP-ED including the light-emitting element ED. The light conversion layer CCL includes a bank BMP, light conversion patterns CCP-R, CCP-G, and CCP-B, and a barrier layer CAP.

The bank BMP may include a black coloring agent for blocking the light. The bank BMP may include a black dye or a black pigment mixed into a base resin. In one or more embodiments, the black coloring agent may include carbon black, a metal, such as chromium, or an oxide thereof.

The bank BMP includes bank apertures BW-OH corresponding to the light-emitting apertures OH. In a plan view, the bank apertures BW-OH overlap with the light-emitting apertures OH and may have a larger area than the light-emitting apertures OH. That is, each of the bank apertures BW-OH may have a larger area than the first to third light-emitting areas EA1, EA2, and EA3 defined by the light-emitting apertures OH.

The light conversion patterns CCP-R, CCP-G, and CCP-B are arranged inside the bank apertures BW-OH. The light conversion patterns CCP-R, CCP-G, and CCP-B may change the optical properties of the source light.

The light conversion patterns CCP-R, CCP-G, and CCP-B may include quantum dots that modify the optical properties of the source light. Each of the light conversion patterns CCP-R, CCP-G, and CCP-B may include the quantum dots that convert the source light into light of a different wavelength. The quantum dot included in the first light conversion pattern CCP-R overlapping the first pixel area PXA-R may be a red quantum dot that converts blue light, which is the source light, into red light. The quantum dot included in the second light conversion pattern CCP-G overlapping the second pixel area PXA-G may be a green quantum dot that converts blue light, which is the source light, into green light. The quantum dot included in the third light conversion pattern CCP-B overlapping the third pixel area PXA-B may be blue quantum dots that converts blue light, which is the source light, into blue light. Each of the light conversion patterns CCP-R, CCP-G, and CCP-B may further include a scatterer.

The light conversion patterns CCP-R, CCP-G, and CCP-B may be formed using an inkjet process. A liquid composition is provided within the bank aperture BW-OH.

The light conversion layer CCL further includes a barrier layer CAP covering one surface (or referred to as a lower surface or a first surface) of the light conversion patterns CCP-R, CCP-G, and CCP-B. The barrier layer CAP may serve to reduce or prevent the penetration of moisture and/or oxygen (hereinafter referred to as “moisture/oxygen”). The barrier layer CAP may block the light conversion patterns CCP-R, CCP-G, and CCP-B from being exposed to moisture/oxygen. The barrier layer CAP may also protect the light conversion patterns CCP-R, CCP-G, and CCP-B from external impact.

In one or more embodiments, the light conversion layer CCL may further include an additional barrier layer CAP-T that covers the other surface (also referred to as an upper surface or a second surface) of the light conversion patterns CCP-R, CCP-G, and CCP-B. The barrier layer CAP and the additional barrier layer CAP-T may cover not only the light conversion patterns CCP-R, CCP-G, and CCP-B but also the bank BMP.

The barrier layer CAP and the additional barrier layer CAP-T may be formed of an inorganic material. Each of the barrier layer CAP and the additional barrier layer CAP-T may further include an organic film, and may be composed of multiple layers.

The color filter layer CFL is located on the light conversion layer CCL. The color filter layer CFL includes a plurality of color filters CF1, CF2, and CF3. Each of the color filters CF1, CF2, and CF3 transmits light within a corresponding wavelength range, and blocks light outside the corresponding wavelength range. The first color filter CF1 of the first pixel area PXA-R may transmit red light, and may block green light and blue light, and the second color filter CF2 of the second pixel area PXA-G may transmit green light, and may block red light and blue light. The third color filter CF3 of the third pixel area PXA-B may transmit blue light, and may block red light and green light. Each of the color filters CF1, CF2, and CF3 may include a base resin, and a dye and/or pigment dispersed in the base resin.

The color filter layer CFL may further include a low-refractive-index layer LR. The low-refractive-index layer LR may be located between the light conversion layer CCL and the color filters CF1, CF2, and CF3. The low-refractive-index layer LR may be located over the light conversion layer CCL to block the light conversion patterns CCP-R, CCP-G, and CCP-B from being exposed to moisture/oxygen. Furthermore, the low-refractive-index layer LR may function as an optical functional layer, such as increasing light extraction efficiency between the light conversion layer CCL and the color filters CF1, CF2, and CF3 or such as reducing or preventing reflected light from entering the light conversion layer CCL. The low-refractive-index layer LR may have a lower refractive index than adjacent layers. The low-refractive-index layer LR may include at least one inorganic layer.

The filling layer FML may be located between the display panel DP and the optical control layer OSL. In one or more embodiments, the filling layer FML may be filled between the display element layer DP-ED and the light conversion layer CCL. The filling layer FML may function as a buffer between the display element layer DP-ED and the light conversion layer CCL. In one or more embodiments, the filling layer FML may perform a shock absorption function, etc., and may increase the strength of the display module DM.

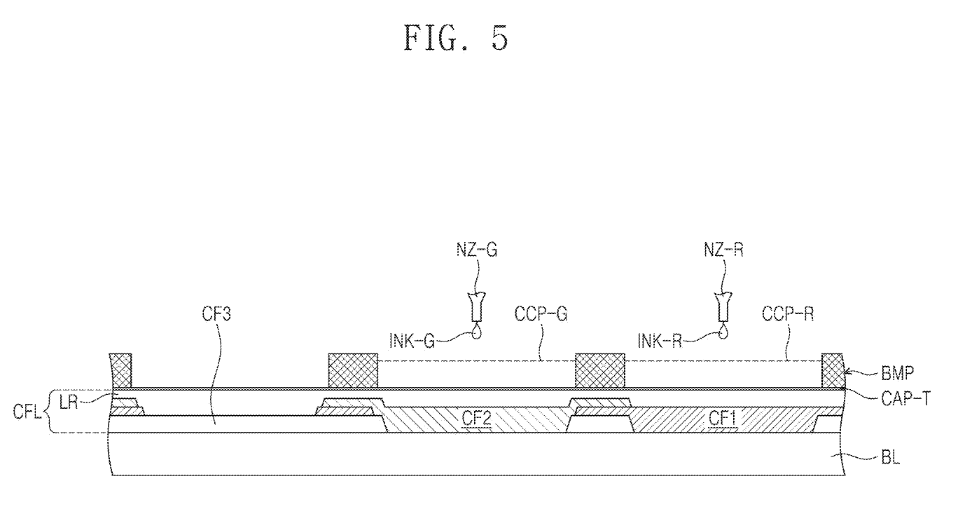

FIG. 5 is a cross-sectional view illustrating one step of a method for manufacturing a display module, according to one or more embodiments of the present disclosure.

Referring to FIG. 5, the bank apertures BW-OH corresponding to the first pixel area PXA-R, the second pixel area PXA-G, and the third pixel area PXA-B may be formed between the banks BMP, and the plurality of light conversion patterns CCP-R, CCP-G, and CCP-B (refer to FIG. 4A) may be formed within the bank apertures BW-OH.

A first color ink INK-R may be provided by a first nozzle NZ-R to the inside of the bank apertures BW-OH overlapping the first pixel area PXA-R, and a second color ink INK-G may be provided by a second nozzle NZ-G to the inside of the bank apertures BW-OH overlapping the second pixel area PXA-G. Each of the bank apertures BW-OH may be defined as a printing area where inks are printed.

The first color ink INK-R and the second color ink INK-G may each be a composition including quantum dots and scatterers. The first color ink INK-R may include red quantum dots and scatterers, and the second color ink INK-G may include green quantum dots and scatterers. In one or more embodiments, a method for manufacturing the display module DM may include performing a thermal curing process or a photocuring process on the compositions provided in the bank apertures BW-OH overlapping the first pixel area PXA-R and the second pixel area PXA-G, thereby forming the first light conversion pattern CCP-R and the second light conversion pattern CCP-G.

The first color ink INK-R and the second color ink INK-G may each be provided using an inkjet process. The first nozzle NZ-R and the second nozzle NZ-G, which provide the first color ink INK-R and the second color ink INK-G, respectively, may be components included in an inkjet printing apparatus, which will be described later.

While FIG. 5 illustrates that the light conversion patterns CCP-R and CCP-G are formed using the inkjet process by way of example, the present disclosure is not limited thereto, and the color filters CF1, CF2, and CF3 (refer to FIG. 4A) or the emission layer EML (refer to FIG. 4A) may also be formed using the inkjet process. A pattern or layer formed using the inkjet process may be referred to as a pattern layer.

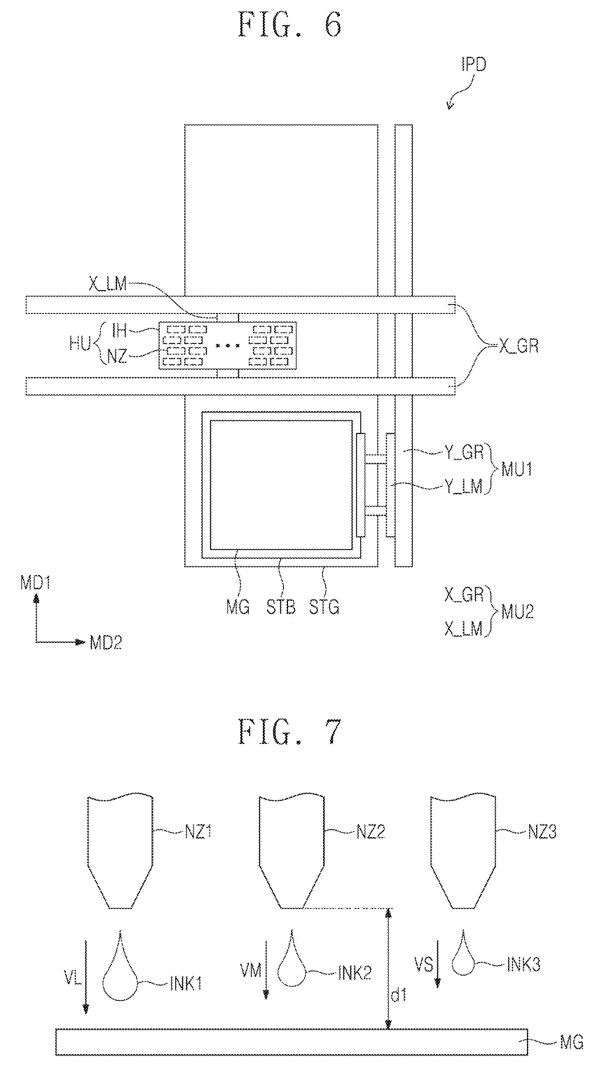

FIG. 6 is a plan view illustrating an inkjet printing apparatus, according to one or more embodiments of the present disclosure.

Referring to FIG. 6, an inkjet printing apparatus IPD may include a stage STG, a support table STB, a head unit HU, a first mover (e.g., a first moving unit) MU1, and a second mover (e.g., a second moving unit) MU2.

The support table STB is located on (e.g., above) the stage STG and may move in a first-axis direction MD1 on the stage STG. A target substrate MG may be located on (e.g., above) the support table STB. In one or more embodiments, a suction hole may be defined in the support table STB. The target substrate MG may be fixed to the support table STB by adsorption method through the suction hole of the support table STB. Therefore, when the support table STB moves, the target substrate MG fixed to the support table STB may move along with the support table STB.

The first mover MU1 may be located at one side of the stage STG. The first mover MU1 may include a first-axis guide rail Y_GR, and a first-axis linear motor Y_LM connected to the first-axis guide rail Y_GR. The first-axis linear motor Y_LM may be coupled to the support table STB. The first-axis linear motor Y_LM may move the support table STB in the first-axis direction MD1. An encoder may be installed in the first-axis linear motor Y_LM to measure the position of the support table STB (e.g., the position of the target substrate MG).

The head unit HU may be located on (e.g., above) the support table STB to face the target substrate MG. When the target substrate MG moves in the first-axis direction MD1, the head unit HU may move in a second-axis direction MD2. The second-axis direction MD2 may be substantially orthogonal to the first-axis direction MD1.

The head unit HU may eject ink onto a printing position (or a printing area) of the target substrate MG while moving in the second-axis direction MD2 when the target substrate MG moves in the first-axis direction MD1. The head unit HU may include an inkjet head IH, and a plurality of nozzles NZ arranged on one side of the inkjet head IH to eject ink. In the present disclosure, the nozzles NZ may be provided on a lower surface of the inkjet head IH. The nozzles NZ may be arranged in the first-axis direction MD1 and the second-axis direction MD2. The head unit HU may further include an ink supply chamber that supplies ink to the inkjet head IH.

The second mover MU2 may be coupled to the head unit HU and may move the head unit HU in the second-axis direction MD2. The second mover MU2 may include a second-axis guide rail X_GR and a second-axis linear motor X_LM connected to the second-axis guide rail X_GR. The second-axis linear motor X_LM may be coupled to the head unit HU. The second-axis linear motor X_LM may move the head unit HU in the second-axis direction MD2.

FIG. 7 is a diagram illustrating an ink drop speed depending on an ink ejection amount of a nozzle, according to one or more embodiments of the present disclosure.

Referring to FIG. 7, a first nozzle NZ1 may eject a first ink INK1 in a first ejection amount at a time, a second nozzle NZ2 may eject a second ink INK2 in a second ejection amount at a time, and a third nozzle NZ3 may eject a third ink INK3 in a third ejection amount at a time. Among the first to third ejection amounts, the first ejection amount is the largest, the third ejection amount is the smallest, and the second ejection amount may be less than the first ejection amount and greater than the third ejection amount. The type and amount of ink ejected from each of the first to third nozzles NZ1, NZ2, and NZ3 are not fixed, and may vary depending on a position.

When the ejection amounts of the first to third inks INK1, INK2, and INK3 ejected from each of the first to third nozzles NZ1, NZ2, and NZ3 are different from each other, the drop speeds of the first to third inks INK1, INK2, and INK3 ejected from each of the first to third nozzles NZ1, NZ2, and NZ3 may also be different from each other. That is, the drop speed may increase as the ejection amount increases. Because a straight-line distance d1 from each of the first to third nozzles NZ1, NZ2, and NZ3 to the target substrate MG is the same, the first ink INK1 ejected from the first nozzle NZ1 having the fastest drop speed may be printed first on the target substrate MG. The drop speed of the first ink INK1 ejected from the first nozzle NZ1 is referred to as a first drop speed VL, the drop speed of the second ink INK2 ejected from the second nozzle NZ2 is referred to as a second drop speed VM, and the drop speed of the third ink INK3 ejected from the third nozzle NZ3 is referred to as a third drop speed VS. For example, when the first drop speed VL is about 5m/s, the second drop speed VM is about 4.9m/s, and the straight-line distance d1 is about 0.5mm, a time difference of approximately 2μs may occur between the time when the first ink INK1 is dropped onto the target substrate MG and the time when the second ink INK2 is dropped onto the target substrate MG. In this case, when the moving speed of the target substrate MG is about 200mm/s, the second ink INK2 is accurately printed at the target position, but the first ink INK1 may be printed before reaching the target position. In detail, a distance difference of approximately 0.4μm may occur between the target position and the actual print position of the first ink INK1.

In this way, when the ink ejection amount is different, the inkjet printing apparatus IPD (refer to FIG. 6) may control the ejection timing of ink from each nozzle based on the ink ejection amount such that the ink ejected from each nozzle is accurately printed at the target position.

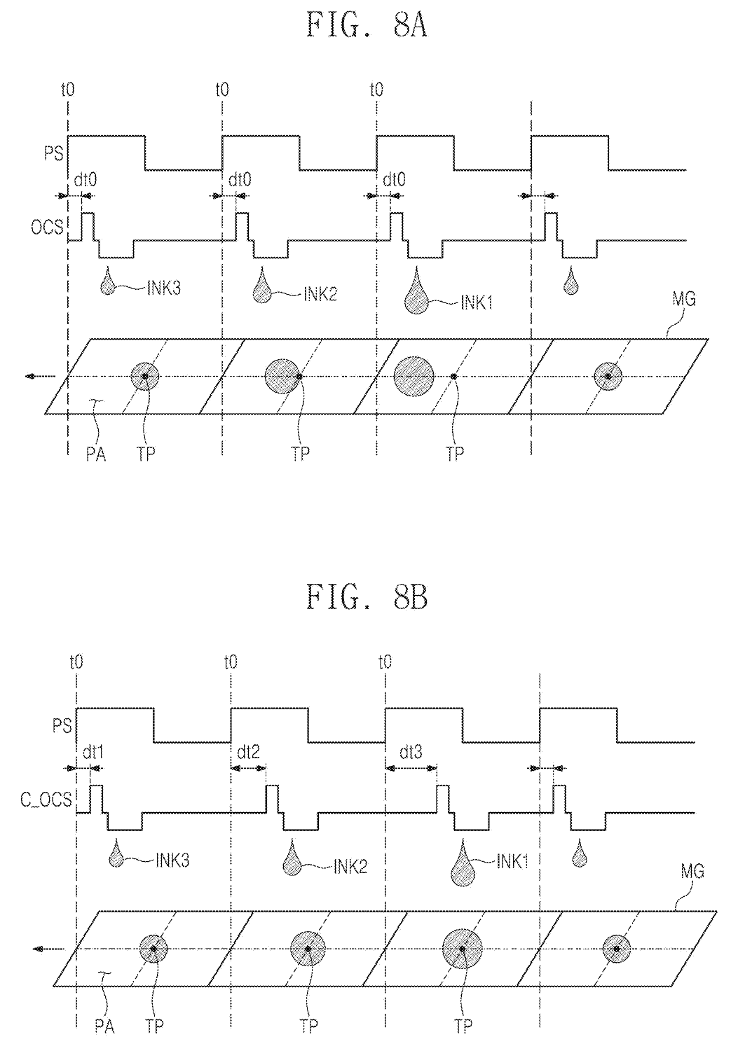

FIG. 8A is a diagram illustrating an ink ejection timing and a printing position depending on an ink ejection amount according to a comparative example, and FIG. 8B is a diagram illustrating an ink ejection timing and a printing position depending on an ink ejection amount according to one or more embodiments of the present disclosure.

Referring to FIG. 8A, an encoder installed in the first-axis linear motor Y_LM (refer to FIG. 6) may output a position signal PS indicating the position of the target substrate MG. The position signal PS may be a square wave signal that periodically has a high state and a low state. In one or more embodiments of the present disclosure, the position signal PS may be switched from the low state to the high state at a time point (hereinafter, an initiation time point t0) when a printing area PA of the target substrate MG and the nozzle NZ (refer to FIG. 6) begin to face each other, and may be switched from the high state to the low state at a time point when a target position TP of the printing area PA and the nozzle NZ face each other.

The head unit HU (refer to FIG. 6) may receive the position signal PS from the encoder installed in the first-axis linear motor Y_LM, and may generate an ejection control signal OCS that determines the ink ejection timing based on the position signal PS. The ejection control signal OCS may be activated at a fixed ejection time point dt0 that is delayed by a time (e.g., predetermined time) from an initiation time point t0. According to the comparative example, because the ejection control signal OCS is activated at the fixed ejection time point dt0 that is delayed by a certain time from the initiation time point t0, regardless of the ink ejection amount, each nozzle NZ may eject the ink at the fixed ejection time point dt0.

An activation period of the ejection control signal OCS may include a high period that pulls ink through a piezoelectric element and a low period that pushes ink through a piezoelectric element. In FIG. 8A, the fixed ejection time point dt0 is illustrated as an initiation time point of the high period, but the present disclosure is not limited thereto. The fixed ejection time point dt0 may be defined as an initiation time point of the low period.

When each nozzle NZ ejects ink at the fixed ejection time point dt0 regardless of the ink ejection amount, the printing position of the ink may not be precisely aligned with the target position TP. For example, the third ink INK3 may be printed accurately on the target position TP, but the first and second inks INK1 and INK2 may be printed before reaching the target position TP because the drop speeds of the first and second inks INK1 and INK2 are faster than that of the third ink INK3. Therefore, a process defect may occur in which the printing positions of the first and second inks INK1 and INK2 are not precisely aligned with the corresponding target position TP.

Referring to FIG. 8B, the head unit HU (refer to FIG. 6) may generate a compensation ejection control signal C_OCS that determines the ink ejection timing based on the position signal PS and the ink ejection amount. The compensation ejection control signal C_OCS may be activated at a variable time from the initiation time point t0 depending on the ink ejection amount. For example, when the third ink INK3 is dropped in the third ejection amount, the compensation ejection control signal C_OCS is activated at a first ejection time point dt1. When the second ink INK2 is dropped in the second ejection amount, the compensation ejection control signal C_OCS is activated at a second ejection time point dt2. The first ejection time point dt1 is a time point delayed by a first delay time from the initiation time point t0, and the second ejection time point dt2 is a time point delayed by a second delay time from the initiation time point t0. The second delay time may be greater than the first delay time. When the first ink INK1 is dropped in the first ejection amount, the compensation ejection control signal C_OCS is activated at a third ejection time point dt3. The third ejection time point dt3 is a time point delayed by a third delay time from the initiation time point t0, and the third delay time may be greater than the second delay time.

The activation period of the compensation ejection control signal C_OCS may include a high period that pulls ink through the piezoelectric element, and a low period that pushes ink through the piezoelectric element. In FIG. 8B, the first to third ejection time points dt1, dt2, and dt3 are defined based on an initiation time point of the high period of the compensation ejection control signal C_OCS, but the present disclosure is not limited thereto. The first to third ejection time points dt1, dt2, and dt3 may be defined based on an initiation time point of the low period of the compensation ejection control signal C_OCS.

In this way, by ejecting the ink at time points delayed by different delay times from the initiation time point t0 depending on the ink ejection amount, the ink ejected from each nozzle NZ may be accurately printed on the target position TP. By varying the ink ejection timing of each nozzle NZ depending on the ink ejection amount, the actual printing position of the ink may be accurately aligned with the target position TP, thereby preventing or reducing process defects.

FIG. 9 is a block diagram of an inkjet printing apparatus, according to one or more embodiments of the present disclosure.

Referring to FIG. 9, the inkjet printing apparatus IPD may include a management controller PMC and a plurality of head units HU1 to HUn. The management controller PMC may receive a control signal CS from a main controller MCU and the position signal PS from the first mover MU1. For example, the position signal PS may be a signal provided from the encoder of the first-axis linear motor Y_LM (refer to FIG. 6).

The management controller PMC may manage and control the overall operation of the inkjet printing apparatus IPD in response to the control signal CS received from the main controller MCU. The management controller PMC may be connected to the plurality of head units HU1 to HUn and may control the operations of the plurality of head units HU1 to HUn. For example, the management controller PMC may provide print image data IP and the position signal PS to each of the head units HU1 to HUn. The print image data IP may include information about the amount of ink ejected from each nozzle NZ (refer to FIG. 6) among the plurality of nozzles NZ provided in each of the head units HU1 to HUn. Additionally, as an example of the present disclosure, the print image data IP may include information about the ejection timing of each nozzle NZ.

Because each of the plurality of head units HU1 to HUn has the same configuration, only the configuration of the first head unit HU1 is illustrated in FIG. 9 as an example.

The first head unit HU1 may include a head interface 110, an image analyzer (e.g., image analysis unit) 120, a mask (e.g., mask unit) 130, an ejection control signal generator (e.g., ejection control signal generation unit) 140, an ejection control signal corrector (e.g., ejection control signal correction unit) 150, and the inkjet head IH.

The first head unit HU1 may receive the print image data IP and the position signal PS from the management controller PMC through the head interface 110. The head interface 110 may provide the print image data IP to the image analyzer 120, and may provide the position signal PS to the ejection control signal generator 140.

The ejection control signal generator 140 may generate an ejection control signal OCS based on the position signal PS. The ejection control signal OCS may be a signal activated at a time point delayed by a fixed time from the initiation time point t0 of the position signal PS (refer to FIG. 8A).

The image analyzer 120 may analyze the print image data IP to extract information (e.g., commands) regarding the ejection timing of each nozzle NZ.

The image analyzer 120 may provide commands to the ejection control signal corrector 150. The ejection control signal corrector 150 may receive the ejection control signal OCS from the ejection control signal generator 140, and may receive the commands from the image analyzer 120. The ejection control signal corrector 150 may vary the activation timing of the ejection control signal OCS based on the commands to generate the compensation ejection control signal C_OCS.

The mask 130 may receive the print image data IP from the image analyzer 120, and may perform masking processing on a portion of the print image data IP indicating the command to generate compensation print image data C_IP. Through the masking processing, information on the ejection timing of each nozzle NZ (refer to FIG. 6) may be removed from the print image data IP. Therefore, the compensation print image data C_IP may only include information regarding the amount of ink ejected from each nozzle NZ.

The inkjet head IH receives the compensation print image data C_IP from the mask 130 and the compensation ejection control signal C_OCS from the ejection control signal corrector 150. Therefore, the inkjet head IH may set the ink ejection amount of each nozzle NZ based on the compensation print image data C_IP and may set the ink ejection timing of each nozzle NZ in response to the compensation ejection control signal C_OCS.

In this way, the inkjet head IH may set different ink ejection timings depending on the ink ejection amount in response to the compensation ejection control signal C_OCS, thereby enabling accurate printing of ink at the target position TP (refer to FIG. 8B) even when each nozzle NZ prints different ejection amounts of ink onto the target substrate MG (refer to FIG. 6), and thereby preventing or reducing process defects.

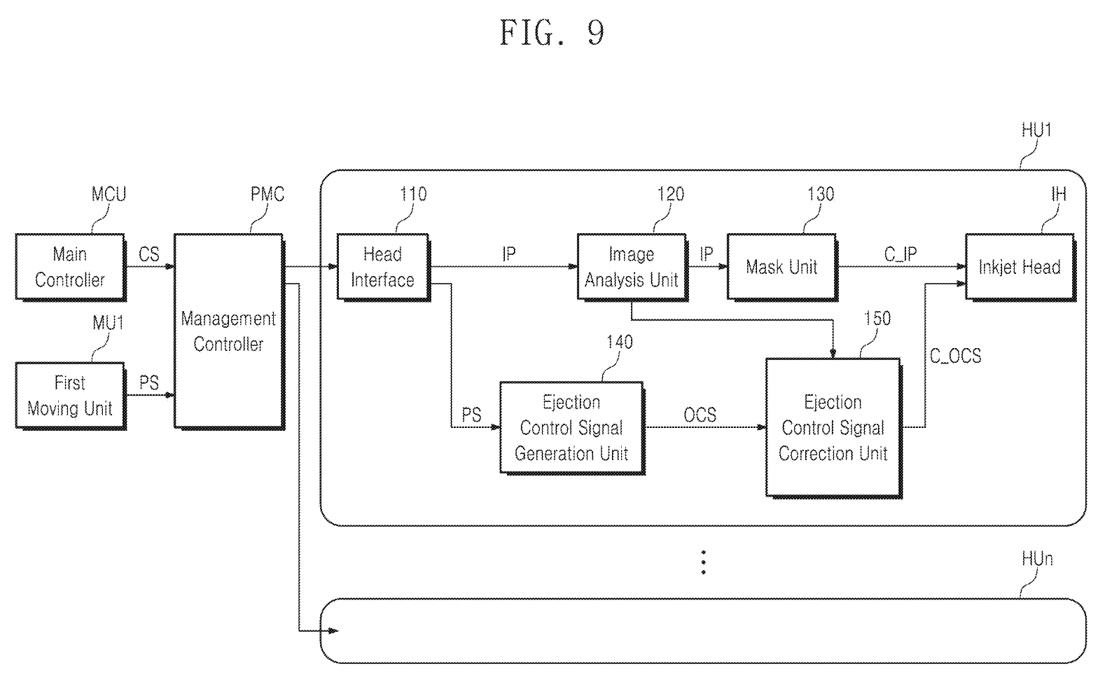

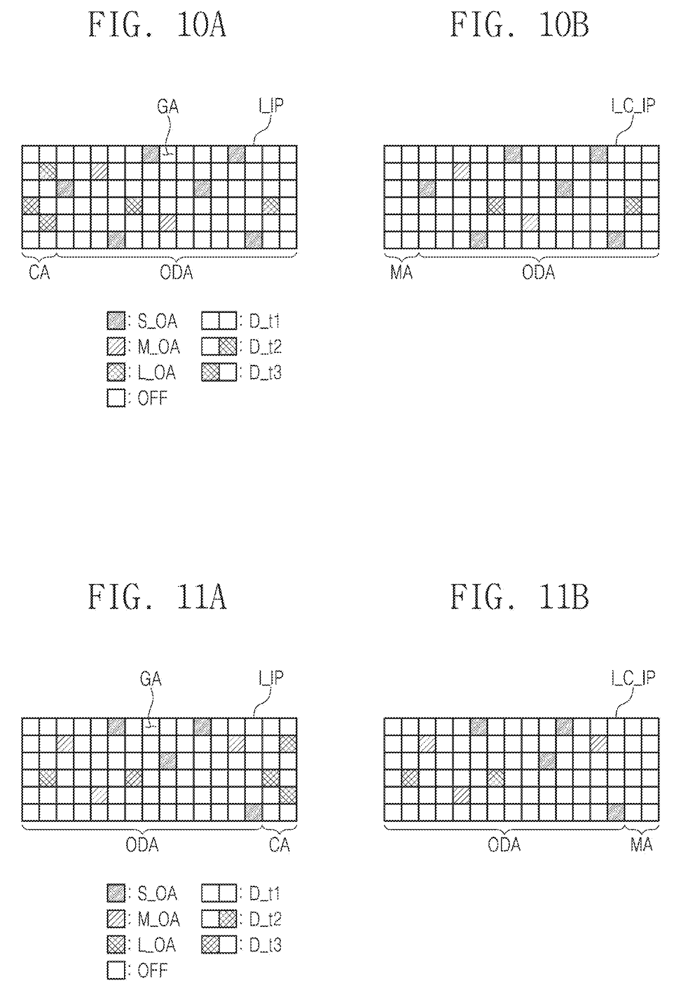

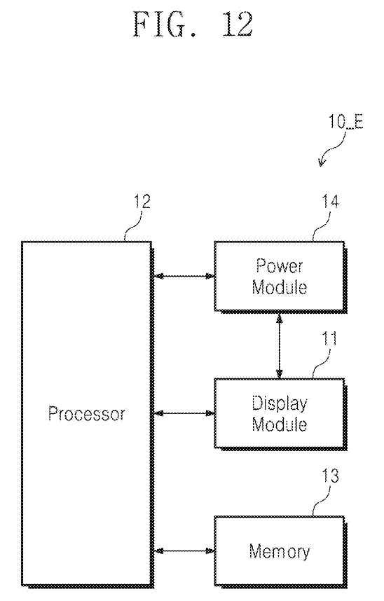

FIG. 10A is a plan view illustrating the print image data IP illustrated in FIG. 9 as an image, and FIG. 10B is a plan view illustrating the compensation print image data C_IP illustrated in FIG. 9 as an image. FIG. 11A is a plan view illustrating the print image data IP illustrated in FIG. 9 as an image, and FIG. 11B is a plan view illustrating the compensation print image data C_IP illustrated in FIG. 9 as an image.

Referring to FIGS. 10A and 11A, a print image I_IP, which is an image of or corresponding to the print image data IP (refer to FIG. 9), may include a plurality of grayscale areas GA. The plurality of grayscale areas GA may each correspond to the plurality of nozzles NZ (refer to FIG. 6) arranged in the inkjet head IH. While FIG. 10A illustrates a structure in which the plurality of grayscale areas GA are arranged in a 6×16 array, the present disclosure is not limited thereto. That is, the number and shape of the plurality of grayscale areas GA included in the print image I_IP may vary.

The print image I_IP may include an ejection data area ODA and a command area CA. The ejection data area ODA may include some of the plurality of grayscale areas GA. As an example of the present disclosure, the grayscale areas GA included in the ejection data area ODA may be arranged in a 6×14 matrix. The grayscale areas GA included in the ejection data area ODA may include information regarding the ejection amount of the corresponding nozzle NZ. As an example of the present disclosure, a first reference grayscale represents a first ejection amount L_OA, a second reference grayscale represents a second ejection amount M_OA, and a third reference grayscale represents a third ejection amount S_OA. The first to third reference grayscales have different values.

As an example of the present disclosure, the ejection amount of each grayscale area in the ejection data area ODA may be set differently for each row. For example, the first row includes at least one grayscale area having the third reference grayscale, the second row includes at least one grayscale area having the second reference grayscale, and the third row includes at least one grayscale area having the first reference grayscale. Therefore, the nozzles NZ in the first row may eject ink at the third ejection amount, the nozzles NZ in the second row may eject ink at the second ejection amount, and the nozzles NZ in the third row may eject ink at the first ejection amount. In addition, some grayscale areas (e.g., white areas) among the grayscale areas GA have a white grayscale (or OFF grayscale), the nozzles NZ corresponding to the white area are turned off, and the ink is not ejected from the turned-off nozzles NZ.

In an example of the present disclosure, the command area CA may be arranged to one side of the ejection data area ODA. Although FIG. 10A illustrates a structure in which the command area CA is arranged to the left side of the ejection data area ODA, the present disclosure is not limited thereto. As illustrated in FIG. 11A, the command area CA may also be arranged to the right side of the ejection data area ODA. Furthermore, the command area CA is not fixed to the left side or the right side, but may be alternately set to the left side or the right side for each print image.

The command area CA may include some of the plurality of grayscale areas GA. In an example of the present disclosure, the grayscale areas GA included in the command area CA may be arranged in a 6×2 matrix. The grayscale areas GA included in the command area CA may include information (e.g., commands) regarding the ink ejection timing of the corresponding nozzle NZ. As an example of the present disclosure, each of the grayscale areas GA included in the command area CA may have one of two command grayscales. For example, among the two command grayscales, a first command grayscale may be identical to the first reference grayscale, and a second command grayscale may be identical to the white grayscale. However, the present disclosure is not limited thereto, and the first and second command grayscales may be selected as two different grayscales from among the first to third reference grayscales and the white grayscale.

In the command area CA, the two grayscale areas are arranged in each row, and information regarding the ink ejection timing may vary depending on the grayscale of each of the two grayscale areas. For example, when both grayscale areas have the white grayscale, a time point (e.g., the first ejection time point dt1 (refer to FIG. 8B)) delayed by a first delay time D_t1 from the initiation time point t0 (refer to FIG. 8B) of the position signal PS may be the ink ejection timing. Meanwhile, when the first grayscale area of the two grayscale areas has the white grayscale and the second grayscale area of the two grayscale areas has the first reference grayscale, a time point (e.g., the second ejection time point dt2 (refer to FIG. 8B)) delayed by a second delay time D_t2 from the initiation time point t0 of the position signal PS may be the ink ejection timing. In addition, when the first grayscale area of the two grayscale areas has the first reference grayscale, and when the second grayscale area of the two grayscale areas has the white grayscale, a time point (e.g., the third ejection time point dt3 (refer to FIG. 8B)) delayed by a third delay time D_t3 from the initiation time point t0 of the position signal PS may be the ink ejection timing.

Because both the first and second grayscale areas in the first row of the command area CA have the white grayscale, the ink ejection timing of the nozzles NZ corresponding to the first row may be set to the first ejection time point dt1. Because the first grayscale area in the second row of the command area CA has the white grayscale, and the second grayscale area in the second row of the command area CA has the first reference grayscale, the ink ejection timing of the nozzles NZ corresponding to the second row is set to the second ejection time point dt2. Because the first grayscale area in the fourth row of the command area CA has the first reference grayscale, and the second grayscale area in the fourth row of the command area CA has the white grayscale, the ink ejection timing of the nozzles NZ corresponding to the fourth row is set to the third ejection time point dt3. In this way, information regarding the ink ejection timing of the nozzles NZ corresponding to each row may be expressed using the grayscales of the two grayscale areas located in the command area CA.

Referring to FIGS. 10B and 11B, a compensation print image I_C_IP, which is an image of the compensation print image data C_IP, includes the ejection data area ODA and a masking area MA. The masking area MA may correspond to the command area CA (refer to FIG. 10A) of the print image I_IP (refer to FIG. 10A).

The masking area MA includes a plurality of grayscale areas (e.g., white areas OFF (refer to FIG. 10A)) having the white grayscale. That is, by masking processing of the mask 130 (refer to FIG. 9), the command area CA of the print image I_IP is converted into the masking area MA, and all grayscale areas of the command area CA may be converted into the white areas OFF having the white grayscale. Therefore, all nozzles NZ corresponding to the masking area MA are turned off, and the ink may not be ejected from the nozzles NZ corresponding to the masking area MA.

Although FIGS. 10A-11B illustrate a case in which the nozzles NZ corresponding to the grayscale area having the white grayscale are turned off, the present disclosure is not limited thereto. For example, when the nozzle NZ corresponding to the grayscale area having a grayscale (e.g., a black grayscale) different from the first to third reference grayscales is turned off, all grayscale areas of the masking area MA may be converted into black areas having the black grayscale.

The ejection data area ODA in the compensation print image I_C_IP maintains the same state as the ejection data area ODA of a print image I_IP. That is, the mask 130 only converts the grayscales of the grayscale areas GA located in the command area CA, and does not convert the grayscales of the grayscale areas GA located in the ejection data area ODA. Accordingly, the inkjet head IH (refer to FIG. 9) that receives the compensation print image data C_IP and the compensation ejection control signal C_OCS may set the ink ejection amount to the corresponding nozzle NZ depending on the grayscale of the ejection data area ODA, and may set the ink ejection timing of each nozzle NZ depending on the compensation ejection control signal C_OCS. Therefore, even if each nozzle NZ prints different ejection amounts of ink on the target substrate MG (refer to FIG. 6), the ink may be accurately printed at the target position TP (refer to FIG. 8B), and as a result, process defects may be prevented or reduced.

The electronic device may be applied to various electronic devices. The electronic device according to one or more embodiments includes the electronic device described above, and may further include modules or devices with additional functions.

FIG. 12 is a block diagram of an electronic device according to one or more embodiments.

Referring to FIG. 12, an electronic device 10_E according to one or more embodiments may include a display module 11, a processor 12, a memory 13, and a power module 14. The display module 11 may correspond to the display module DM described above.

The processor 12 may include at least one of a central processing unit (CPU), an application processor (AP), a graphics processing unit (GPU), a communication processor CP, an image signal processor (ISP), or a controller.

The memory 13 may store data information suitable for operations of the processor 12 or the display module 11. When the processor 12 executes an application stored in the memory 13, an image data signal and/or an input control signal is transferred to the display module 11, and the display module 11 may process the received signal and may output image information through a display screen.

The power module 14 may include a power supply module, such as a power adapter or a battery device, and a power conversion module that converts power supplied by the power supply module to generate power required for the operation of the electronic device 10_E.

At least one of the components of the electronic device 10_E described above may be included in the electronic device according to the embodiments described above. In addition, some of the individual modules functionally included in one module may be included in the electronic device, and others may be provided separately from the electronic device. For example, the electronic device may include the display module 11, and the processor 12, the memory 13, and the power module 14 may be provided in the form of another device within the electronic device 10_E other than the electronic device.

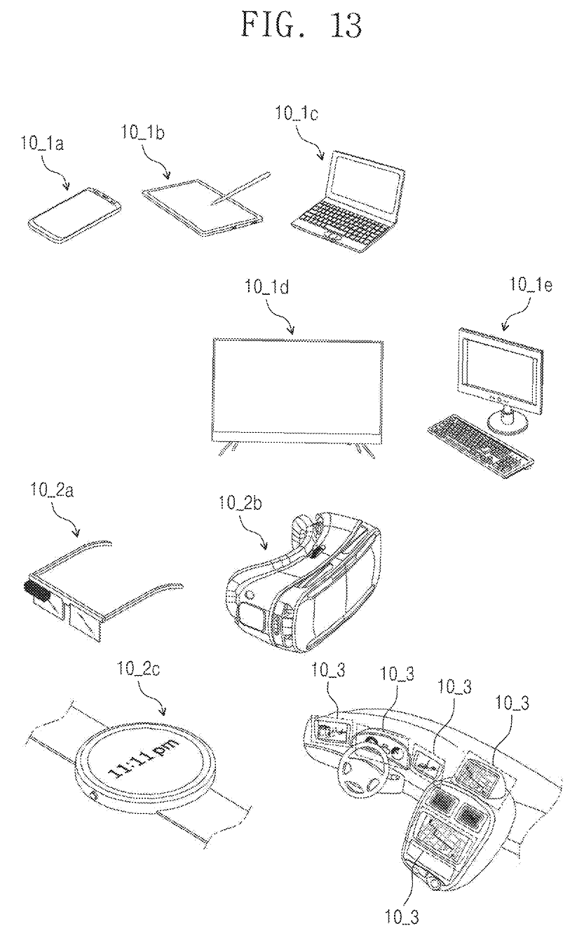

FIG. 13 is a schematic diagram illustrating electronic devices, according to various embodiments.

Referring to FIG. 13, various electronic devices to which the electronic device according to the embodiments is applied may include not only image display electronic devices, such as a smart phone 10_1a, a tablet PC 10_1b, a laptop computer 10_1c, a TV 10_1d, a desk monitor 10_1e, but also wearable electronic devices including display modules, such as smart glasses 10_2a, a head-mounted display 10_2b, a smart watch 10_2c, etc., and vehicle electronic devices 10_3 including display modules, such as a CID (Center Information Display) placed on an instrument panel, a center fascia, or a dashboard of a vehicle, a room mirror display, etc.

According to one or more embodiments of the present disclosure, the inkjet head responds to the compensation ejection control signal and sets the ink ejection timing differently depending on the ink ejection amount, so that even if each nozzle prints a different ejection amount of ink on the target substrate, the ink may be accurately printed at the target position, thereby preventing or reducing process defects.

Although the present disclosure has been described above with reference to embodiments thereof, it will be understood by those skilled in the art or having ordinary knowledge in the art that various modifications and substitutions are possible, without departing from the present disclosure as set forth in the claims below.

Accordingly, the present disclosure is not limited to the detailed description of this specification, but should be determined by the claims, with functional equivalents thereof to be included therein.

What is claimed is:

1. An inkjet printing apparatus comprising:
a stage;
a support table above the stage and to which a target substrate is fixed;
a first mover configured to move the support table in a first-axis direction above the stage;
a head unit above the target substrate, configured to eject ink onto a printing area of the target substrate, and configured to set an ejection timing of the ink differently depending on an ejection amount of the ink; and
a second mover configured to move the head unit in a second-axis direction.

2. The inkjet printing apparatus of claim 1, wherein the head unit comprises an inkjet head, and nozzles on a lower surface of the inkjet head and comprising:
a first nozzle configured to eject the ink in a first ejection amount;
a second nozzle configured to eject the ink in a second ejection amount that is less than the first ejection amount; and
a third nozzle configured to eject the ink in a third ejection amount that is less than the second ejection amount.

3. The inkjet printing apparatus of claim 2, wherein the head unit is configured to receive a position signal indicating a position of the target substrate, and is configured to determine the ejection timing of the ink with respect to the first nozzle, the second nozzle, and the third nozzle based on the position signal and the first ejection amount, the second ejection amount, and the third ejection amount.

4. The inkjet printing apparatus of claim 3, wherein the third nozzle is configured to eject the ink at a first ejection time point that is delayed by a first delay time from an initiation time point of the position signal,
wherein the second nozzle is configured to eject the ink at a second ejection time point that is delayed by a second delay time from the initiation time point that is greater than the first delay time, and
wherein the first nozzle is configured to eject the ink at a third ejection time point that is delayed by a third delay time from the initiation time point that is greater than the second delay time.

5. The inkjet printing apparatus of claim 3, wherein the head unit further comprises:
an image analyzer configured to receive and analyze print image data to extract a command with respect to the ejection timing of the ink of the nozzles;
an ejection control signal generator configured to generate an ejection control signal based on the position signal; and
an ejection control signal corrector configured to receive the command from the image analyzer, to receive the ejection control signal from the ejection control signal generator, and to change an activation timing of the ejection control signal based on the command to generate a compensation ejection control signal.

6. The inkjet printing apparatus of claim 5, wherein the head unit further comprises a mask configured to receive the print image data from the image analyzer and to output compensation print image data by masking the command among the print image data.

7. The inkjet printing apparatus of claim 6, wherein a print image corresponding to the print image data comprises:
an ejection data area comprising grayscale areas comprising ejection amount information with respect to a corresponding nozzle; and
a command area comprising grayscale areas comprising information with respect to the ejection timing of the ink of the corresponding nozzle.

8. The inkjet printing apparatus of claim 7, wherein a first one of the grayscale areas corresponding to the first nozzle has a first reference grayscale,
wherein a second one of the grayscale areas corresponding to the second nozzle has a second reference grayscale,
wherein a third one of the grayscale areas corresponding to the third nozzle has a third reference grayscale, and
wherein the first reference grayscale, the second reference grayscale, and the third reference grayscale have different respective values.

9. The inkjet printing apparatus of claim 8, wherein one or more of the grayscale areas of the ejection data area have a white grayscale, and
wherein the head unit is configured to turn off the nozzle corresponding to the one or more grayscale areas having the white grayscale.

10. The inkjet printing apparatus of claim 9, wherein the grayscale areas of the command area have one of a first command grayscale or a second command grayscale, and
wherein the first command grayscale and the second command grayscale are two different grayscales from among the first reference grayscale, the second reference grayscale, the third reference grayscale, and the white grayscale.

11. The inkjet printing apparatus of claim 9, wherein a compensation print image corresponding to the compensation print image data comprises the ejection data area and a masking area that corresponds to the command area of the print image.

12. The inkjet printing apparatus of claim 11, wherein the masking area comprises one or more of the grayscale areas having the white grayscale such that one or more of the nozzles corresponding to the masking area are configured to be turned off.

13. A method of manufacturing a display module, the method comprising:
fixing a target substrate to a support table above a stage;
moving the support table in a first-axis direction above the stage by a first mover;
placing a head unit, which is configured to eject ink onto a printing area of the target substrate, above the target substrate;
moving the head unit in a second-axis direction above the target substrate by a second mover;
determining an ejection amount of the ink and an ejection timing of the ink based on print image data and a position signal; and
ejecting the ink onto the printing area to form a pattern layer.

14. The method of claim 13, wherein the head unit comprises an inkjet head, and nozzles on a lower surface of the inkjet head and comprising:
a first nozzle configured to eject the ink in a first ejection amount;
a second nozzle configured to eject the ink in a second ejection amount that is less than the first ejection amount; and
a third nozzle configured to eject the ink in a third ejection amount that is less than the second ejection amount.

15. The method of claim 14, further comprising receiving, by the head unit, the position signal indicating a position of the target substrate, and
determining the ejection timing of the ink of the first nozzle, the second nozzle, and the third nozzle based on the position signal and the first ejection amount, the second ejection amount, and the third ejection amount.

16. The method of claim 15, wherein the third nozzle is configured to eject the ink at a first ejection time point that is delayed by a first delay time from an initiation time point of the position signal,
wherein the second nozzle is configured to eject the ink at a second ejection time point that is delayed by a second delay time from the initiation time point that is greater than the first delay time, and
wherein the first nozzle is configured to eject the ink at a third ejection time point that is delayed by a third delay time from the initiation time point that is greater than the second delay time.

17. The method of claim 14, wherein the determining of the ejection amount of the ink and the ejection timing of the ink comprises:
analyzing the print image data to extract a command with respect to the ejection timing the ink of the nozzles;
generating an ejection control signal based on the position signal; and
generating a compensation ejection control signal by changing an activation timing of the ejection control signal based on the command.

18. The method of claim 17, wherein the determining of the ejection amount of the ink and the ejection timing of the ink further comprises outputting compensation print image data by masking the command among the print image data, and
wherein the method further comprises controlling, with the inkjet head, the ejection amount and the ejection timing of the ink with respect to the nozzles in response to the compensation print image data and the compensation ejection control signal.

19. The method of claim 18, wherein a print image corresponding to the print image data comprises:
an ejection data area comprising grayscale areas comprising ejection amount information with respect to a corresponding nozzle; and
a command area comprising grayscale areas comprising information with respect to the ejection timing of the ink of the corresponding nozzle,
wherein a compensation print image corresponding to the compensation print image data comprises the ejection data area and a masking area that corresponds to the command area of the print image, and
wherein the method further comprises turning off all of ones of the nozzles corresponding to the masking area.

20. An electronic device comprising:
a display module configured to display an image; and
a processor configured to process and provide an image signal to the display module,
wherein the display module is manufactured by:
fixing a target substrate to a support table above a stage;
moving the support table in a first-axis direction above the stage by a first mover;
placing a head unit that is configured to eject ink onto a printing area of the target substrate above the target substrate;
moving the head unit in a second-axis direction above the target substrate by a second mover;
determining an ejection amount of the ink and an ejection timing of the ink based on print image data and a position signal; and
ejecting the ink onto the printing area to form a pattern layer.
